(19) United States
(12) Patent Application Publication
(10) Pub. No.: US 2015/0155323 A1
(43) Pub. Date: Jun. 4, 2015

(54) CHIP-STACKED IMAGE SENSOR HAVING HETEROGENEOUS JUNCTION STRUCTURE AND METHOD FOR MANUFACTURING SAME

(71) Applicant: SiliconFile Technologies Inc., Seongnam-si, Gyeonggi-do (KR)

(72) Inventors: Heui Gyun Ahn, Seongnam-si (KR); Jun Ho Won, Seoul (KR)

(21) Appl. No.: 14/399,735

(22) PCT Filed: May 10, 2012
(86) PCT No.: PCT/KR2012/003680

§ 371 Date: Nov. 7, 2014

(30) Foreign Application Priority Data
May 7, 2012 (KR) 10-2012-0047946

(51) Int. Cl. H01L 27/146

(52) U.S. Cl. CPC H01L 27/14636; H01L 27/14687; H01L 27/14632

(57) ABSTRACT

The present invention relates to a chip-stacked image sensor and to a method for manufacturing the same. More particularly, the present invention relates to a chip-stacked image sensor having a heterogeneous junction structure and to a method for manufacturing the same, in which a first semiconductor chip and a second semiconductor chip are manufactured using substrate materials suitable for the characteristics of sensors formed on each semiconductor substrate, and the semiconductor chips are stacked to form an image sensor. According to the chip-stacked image sensor having a heterogeneous junction structure and the method for manufacturing the same, the material for a first semiconductor substrate used in a first semiconductor chip and the material for a second semiconductor substrate used in a second semiconductor chip are different from each other, thus enabling characteristics of sensors formed on each semiconductor chip to be properly exhibited.

### TECHNICAL FIELD

The present invention relates to a chip-stacked image sensor and a manufacturing method thereof, and more particularly to a chip-stacked image sensor having a heterojunction structure and a manufacturing method thereof, in which the chip-stacked image sensor is manufactured by manufacturing a first semiconductor chip and a second semiconductor chip using substrate materials suitable for the characteristics of sensors formed on the semiconductor chips, respectively, and then stacking the semiconductor chips on each other.

### BACKGROUND ART

In the semiconductor industry, packaging technology for integrated circuits has continued to develop in order to satisfy the demand for miniaturization and mounting reliability. Also, with the recent demand for high performance of electric and electronic products together with the miniaturization thereof, various three-dimensional (3D) wafer stacking technologies for vertically stacking two or more semiconductor chips or semiconductor packages have been developed.

In such wafer stacking technologies, a three-dimensional (3D) device is manufactured by stacking wafers, subjecting the stack to a thinning process of grinding the backside of the wafers to reduce the thickness, and subjecting the thinned stack to subsequent processes, followed by sawing and packaging.

In such wafer stacking technologies, a chip-stacked image sensor having a three-dimensional (3D) structure is manufactured by subjecting a first semiconductor chip and a second semiconductor chip to the respective processes, and then putting bonding pads, formed on the two semiconductor chips, respectively, on each other so as to come into contact with each other.

In this conventional chip-stacked image sensor, the first semiconductor chip and the second semiconductor chip have all been manufactured using a silicon (Si)-based substrate for high-speed and high-capacity data processing without taking into consideration the characteristics of a sensor formed in each of the semiconductor chips. For this reason, there is a problem in that the characteristics required for each sensor are not properly exhibited.

### DISCLOSURE

### Technical Problem

It is an object of the present invention to provide a chip-stacked image sensor having a heterojunction structure, in which the chip-stacked image sensor is manufactured by manufacturing a first semiconductor chip and a second semiconductor chip using substrate materials suitable for the characteristics of sensors formed in the semiconductor chips, respectively, and then stacking the semiconductor chips on each other, so that the characteristics of the sensor formed in each of the semiconductor chips can be properly exhibited.

Another object of the present invention is to provide a method for manufacturing a chip-stacked image sensor having a heterojunction structure, in which the chip-stacked image sensor is manufactured by manufacturing a first semiconductor chip and a second semiconductor chip using substrate materials suitable for the characteristics of sensors formed in the semiconductor chips, respectively, and then stacking the semiconductor chips on each other, so that the characteristics of the sensor formed on each of the semiconductor chips can be properly exhibited.

### Technical Solution

To achieve the above objects, an embodiment of the present invention provides a chip-stacked image sensor having a heterojunction structure, the chip-stacked image sensor including: a first semiconductor chip having, formed on a first semiconductor substrate, a photodiode and a first pad configured to transfer an image charge, which corresponds to an image signal sensed by the photodiode, to the outside of the first semiconductor substrate; and a second semiconductor chip having, formed on a second semiconductor substrate, a second pad that is bonded to the first pad, and a circuit region configured to output the image signal, transferred from the first semiconductor chip, to the outside of the second semiconductor chip, wherein the first semiconductor substrate and the second semiconductor substrate are made of different materials.

Another embodiment of the present invention provides a chip-stacked image sensor having a heterojunction structure, the chip-stacked image sensor including: a first semiconductor chip having, formed on a first semiconductor substrate, a photodiode, a transmission transistor configured to transmit an image charge, which corresponds to an image signal sensed by the photodiode, to a floating diffusion region, and a first pad configured to transfer the image charge, which corresponds to the image signal sensed by the photodiode, to the outside of the first semiconductor substrate; and a second semiconductor chip having, formed on a second semiconductor substrate, a second pad that is bonded to the first pad, and a circuit region configured to output the image signal, transferred from the first semiconductor chip, to the outside of the second semiconductor chip, wherein the first semiconductor substrate and the second semiconductor substrate are made of different materials.

Still another embodiment of the present invention provides a method for manufacturing a chip-stacked image sensor having a heterojunction structure, the method including the steps of: forming a first semiconductor chip having, formed on a first semiconductor substrate, a photodiode and a first pad configured to transfer an image charge, which corresponds to an image signal sensed by the photodiode, to the outside of the first semiconductor substrate; forming a second semiconductor chip having, formed on a second semiconductor substrate, a second pad that is bonded to the first pad, and a circuit region configured to output the image signal, transferred from the first semiconductor chip, to the outside of the second semiconductor chip; pretreating the first semiconductor chip and the second semiconductor chip before bonding; and bringing the first pad of the pretreated first semiconductor chip and the second pad of the pretreated second semiconductor chip into contact with each other so as to face each other, thereby bonding the first semiconductor chip and the second semiconductor chip to each other, wherein the first semiconductor substrate and the second semiconductor substrate are made of different materials.

Yet another embodiment of the present invention provides a method for manufacturing a chip-stacked image sensor having a heterojunction structure, the method including the steps of: forming a first semiconductor chip having, formed on a first semiconductor substrate, a photodiode, a transmission transistor configured to transmit an image charge, which corresponds to an image signal sensed by the photodiode, to a floating diffusion region, and a first pad configured to transfer the image charge, which corresponds to the image signal sensed by the photodiode, to the outside of the first semiconductor substrate; forming a second semiconductor chip having, formed on a second semiconductor substrate, a second pad that is bonded to the first pad, and a circuit region configured to output the image signal, transferred from the first semiconductor chip, to the outside of the second semiconductor chip; pretreating the first semiconductor chip and the second semiconductor chip before bonding; and bringing the first pad of the pretreated first semiconductor chip and the second pad of the pretreated second semiconductor chip into contact with each other so as to face each other, thereby bonding the first semiconductor chip and the second semiconductor chip to each other, wherein the first semiconductor substrate and the second semiconductor substrate are made of different materials.

### Advantageous Effects

A chip-stacked image sensor having a heterojunction structure according to the present invention and a manufacturing method thereof have an advantage in that, because a first semiconductor substrate that is used in a first semiconductor chip, and a second semiconductor substrate that is used in a second semiconductor chip, are made of different materials, the characteristics of a sensor formed in each of the semiconductor chips can be properly exhibited.

### DESCRIPTION OF DRAWINGS

FIG. 1 is a cross-sectional view of stacked semiconductor chips in a chip-stacked image sensor having a heterojunction structure according to an embodiment of the present invention.

FIG. 2 is a cross-sectional view of stacked semiconductor chips in a chip-stacked image sensor having a heterojunction structure according to another embodiment of the present invention.

FIG. 3 is a process flow chart showing a method for manufacturing a chip-stacked image sensor having a heterojunction structure according to an embodiment of the present invention.

FIG. 4 is a process flow chart showing a method for manufacturing a chip-stacked image sensor having a heterojunction structure according to another embodiment of the present invention.

### BEST MODE

Hereinafter, the present invention will be described in further detail with reference to the accompanying drawings.

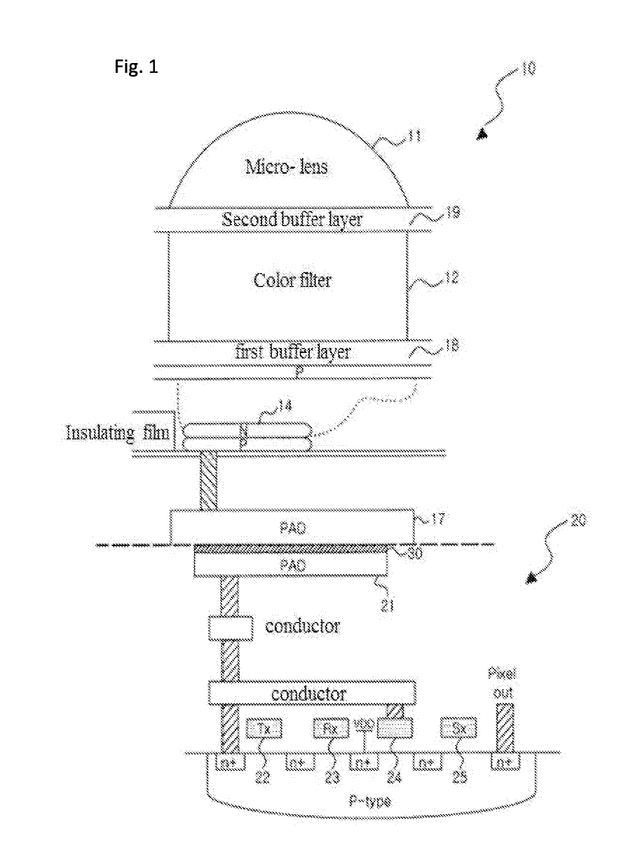

FIG. 1 is a cross-sectional view of stacked semiconductor chips in a chip-stacked image sensor having a heterojunction structure according to an embodiment of the present invention.

As shown in FIG. 1, a chip-stacked image sensor having a heterojunction structure according to the present invention comprises a first semiconductor chip 10 and a second semiconductor chip 20, in which a first semiconductor substrate forming the first semiconductor chip 10, and a second semiconductor substrate forming the second semiconductor chip 20, are made of different materials.

On the first semiconductor substrate of the first semiconductor chip 10, there are formed a photodiode 14 and a first pad 17 configured to transfer an image charge, which corresponds to an image signal sensed by the photodiode, to the outside of the first semiconductor chip 10.

A first buffer layer 18, a color filter 12, a second buffer layer 19 and a micro-lens 11, which are formed above the photodiode 14 on the first semiconductor substrate, are known, and thus the detailed description thereof is omitted.

On the second semiconductor substrate of the second semiconductor chip 20, there are formed a second pad 21 bonded to the first pad 17, and a circuit region configured to output the image charge, transferred from the first semiconductor chip 10, to the outside of the second semiconductor chip 20.

In the circuit region located on the second semiconductor chip 20, there are formed a transmission transistor 22, a reset transistor 23, a source follower transistor 24, a blocking switch transistor 25, a read-out circuit, a vertical/horizontal decoder, a correlated double sampling (CDS) circuit which is involved in a sensor operation and image quality, an analog circuit, an analog-digital converter (ADC), and a digital circuit.

The first semiconductor substrate forming the first semiconductor chip 10 is preferably a substrate made of Ge, SiGe, GaAs, GaN, InP, InGaAs or InGaZnO in view of the characteristics of the sensor unit that is formed in the first semiconductor chip 10. In addition, the first semiconductor substrate may also be an epitaxial substrate obtained by allowing Ge, SiGe, GaAs, GaN, InP, InGaAs to InGaZnO to grow into a single crystal on a silicon (Si) substrate. Alternatively, it may be a GeOI, SiGeOI, GaAsOI, GaNOI, InPOI, InGaAsOI or InGaZnOOI substrate obtained by forming an insulating film on each substrate material so as to have silicon-on-insulator (SOI) characteristics.

Meanwhile, the second semiconductor substrate forming the second semiconductor chip 20 is preferably a silicon (Si) substrate.

The second semiconductor substrate forming the second semiconductor chip 20 may be a non-silicon substrate such as sapphire or SiGe, depending on the characteristics thereof. In other words, the first substrate and the second substrate are made of different materials regardless of the kind of material of the second substrate, and the first semiconductor chip 10 and the second semiconductor chip 20 are stacked by bonding so as to form a single circuit.

Preferably, the second substrate is a silicon (Si) substrate, and the first substrate is a non-silicon (non-Si) substrate.

For example, when a sensor that is formed in the first semiconductor chip 10 is an infrared ray sensor, the first semiconductor chip is formed using a first semiconductor substrate made of a germanium (Ge)-based material that is highly sensitive to infrared rays, and the second semiconductor chip is formed using a second semiconductor substrate made of a silicon (Si) material that enables high-speed data processing, so that infrared ray sensitization and high-speed data processing can all be performed.

Meanwhile, a sensor that is formed in the first semiconductor chip 10 can be fabricated using a Micro-Electro-Mechanical System (MEMS) or other methods, and the first semiconductor chip can be formed using a substrate made of a material that enables the characteristics of this sensor to be properly exhibited.

In the prior art, sensor elements in a sensor having a chip-stacked structure were uniformly formed on a silicon substrate. On the contrary, the present invention is characterized in that a substrate made of a material that enables the characteristics of each sensor element to be properly exhibited is selected and used.

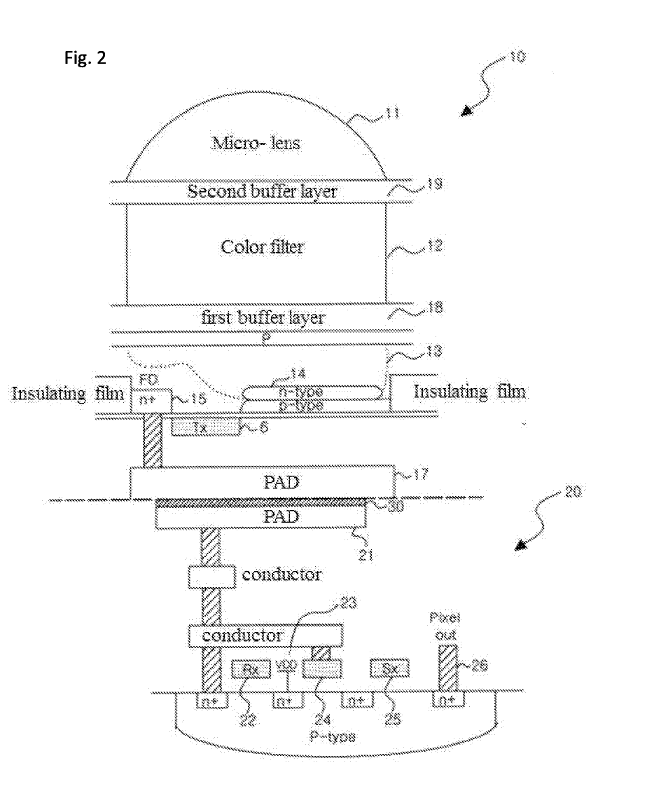

FIG. 2 is a cross-sectional view of stacked semiconductor chips in a chip-stacked image sensor having a heterojunction structure according to another embodiment of the present invention.

As shown in FIG. 2, a chip-stacked image sensor having a heterojunction structure according to another embodiment of the present invention comprises a first semiconductor chip 10 and a second semiconductor chip 20, in which a first semiconductor substrate forming the first semiconductor chip 10, and a second semiconductor substrate forming the second semiconductor chip 20, are made of different materials.

On the first semiconductor substrate of the first semiconductor chip 10, there are formed a photodiode 14, a transmission transistor 6 configured to transmit an image charge, which corresponds to an image signal sensed by the photodiode 14, to a floating diffusion region 15, and a first pad 17 configured to transfer the image charge, which corresponds to the image signal sensed by the photodiode 14, to the outside of the first semiconductor chip 10.

The chip-stacked image sensor having a heterojunction structure according to another embodiment of the present invention as shown in FIG. 2 is the same as the chip-stacked image sensor having the heterojunction structure as shown in FIG. 1, except that the first semiconductor chip 10 further comprises the transmission transistor 6 in addition to the photodiode 14. Thus, the detailed description of other elements is omitted.

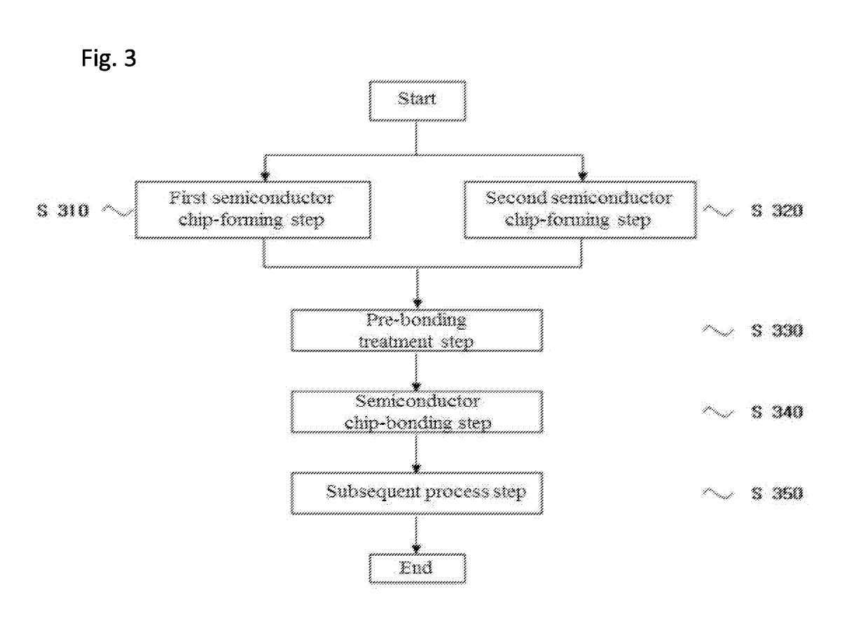

FIG. 3 is a process flow chart showing a method for manufacturing a chip-stacked image sensor having a heterojunction structure according to an embodiment of the present invention.

As shown in FIG. 3, a method for manufacturing a chip-stacked image sensor having a heterojunction structure according to an embodiment of the present invention comprises a first semiconductor chip-forming step (S310), a second semiconductor chip-forming step (S320), a pre-bonding treatment step (S330), a semiconductor chip-bonding step (S340) and a subsequent process step (S350).

In the first semiconductor chip-forming step (S310), a first semiconductor chip is formed, which has, formed on a first semiconductor substrate, a photodiode and a first pad configured to transfer an image charge, which corresponds to an image signal sensed by the photodiode, to the outside of the first semiconductor chip.

In the second semiconductor chip-forming step (S320), a second semiconductor chip is formed, which has, formed on a second semiconductor substrate, a second pad that is bonded to the first pad, and a circuit region configured to output the image charge, transferred from the first semiconductor chip, to the outside of the second semiconductor chip.

Specifically, in the second semiconductor chip-forming step (S320), a circuit region is formed, which has formed therein a transmission transistor, a reset transistor, a source follower transistor, a blocking switch transistor, a read-out circuit, a vertical/horizontal decoder, a correlated double sampling (CDS) circuit which is involved in a sensor operation and image quality, an analog circuit, an analog-digital converter (ADC) and a digital circuit.

The first semiconductor chip-forming step (S310) and the second semiconductor chip-forming step (S320) may be performed simultaneously or in any order. In addition, the first semiconductor chip-forming step (S310) and the second semiconductor chip-forming step (S320) may be performed separately using different process technologies.

In the pre-bonding treatment step (S330), the surface of the first semiconductor chip and the surface of the second semiconductor chip, which are to be bonded to each other, are pretreated using a process such as plasma treatment, cleaning operation or surface treatment.

Next, in the semiconductor chip-bonding step (S340), the first pad of the pretreated first semiconductor chip 10 and the second pad of the pretreated second semiconductor chip are brought into contact with each other in such a manner as to face each other, thereby bonding the first semiconductor chip and the second semiconductor chip to each other.

Herein, the first semiconductor substrate that is used in the first semiconductor chip-forming step (S310), and the second semiconductor substrate that is used in the second semiconductor chip-forming step (S320), are made of different materials.

Specifically, in the first semiconductor chip-forming step (S310), the first semiconductor chip is preferably formed using a first semiconductor substrate made of Ge, SiGe, GaAs, GaN, InP, InGaAs or InGaZnO depending on the characteristics of a sensor unit to be formed in the first semiconductor chip.

Meanwhile, in the first semiconductor chip-forming step (S310), a first semiconductor substrate obtained by allowing Ge, SiGe, GaAs, GaN, InP, InGaAs or InGaZnO to epitaxially grow into a single crystal on a silicon (Si) substrate may be used. In addition, the first semiconductor substrate may also be a GeOI, SiGeOI, GaAsOI, GaNOI, InPOI, InGaAsOI or InGaZnOOI substrate obtained by forming an insulating film on each substrate material so as to have silicon-on-insulator (SOI) characteristics.

In this case, in the second semiconductor chip-forming step (S320), the second semiconductor chip is preferably formed using a second semiconductor chip made of silicon (Si).

Meanwhile, in a subsequent process step (S350) following the semiconductor chip-bonding step (S340), a color filter or a micro-lens is formed.

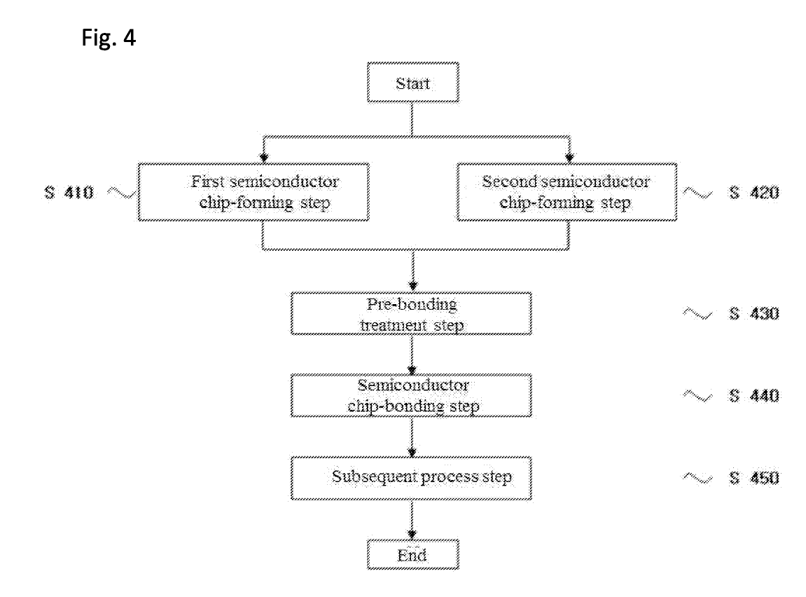

FIG. 4 is a process flow chart showing a method for manufacturing a chip-stacked image sensor having a heterojunction structure according to another embodiment of the present invention.

As shown in FIG. 4, a method for manufacturing a chip-stacked image sensor having a heterojunction structure according to another embodiment of the present invention comprises a first semiconductor chip-forming step (S410), a second semiconductor chip-forming step (S420), a pre-bonding treatment step (S430), a semiconductor chip-boding step (S440) and a subsequent process step (S450).

In the first semiconductor chip-forming step (S410), a first semiconductor chip is formed, which has, formed on a first semiconductor substrate, a photodiode, a transmission transistor configured to transmit an image charge, which corresponds to an image signal sensed by the photodiode, to a floating diffusion region, and a first pad configured to transfer the image charge, which corresponds to the image signal sensed by the photodiode, to the outside of the first semiconductor chip.

Meanwhile, the method for manufacturing the chip-stacked image sensor having the heterojunction structure according to the embodiment of the present invention as shown in FIG. 4 is the same as the method for manufacturing the chip-stacked image sensor having the heterojunction structure according to the embodiment of the present invention as shown in FIG. 3, except that the transmission transistor is further formed in addition to the photodiode on the first semiconductor chip in the first semiconductor chip-forming step (S410). Thus, the detailed description of the second semiconductor chip-forming step (S420), the pre-bonding treatment step (S430), the semiconductor chip-boding step (S440) and the subsequent process step (S450) is omitted.

As described above, a chip-stacked image sensor having a heterojunction structure according to the present invention and a manufacturing method thereof have an advantage in that, because a first semiconductor substrate that is used in a first semiconductor chip, and a second semiconductor substrate that is used in a second semiconductor chip, are made of different materials, the characteristics of a sensor formed in each of the semiconductor chips can be properly exhibited.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A chip-stacked image sensor having a heterojunction structure, the chip-stacked image sensor comprising:
a first semiconductor chip having, formed on a first semiconductor substrate, a photodiode and a first pad configured to transfer an image charge, which corresponds to an image signal sensed by the photodiode, to an outside of the first semiconductor substrate; and
a second semiconductor chip having, formed on a second semiconductor substrate, a second pad that is bonded to the first pad, and a circuit region configured to output the image charge, transferred from the first semiconductor chip, to the outside of the second semiconductor chip,
wherein the first semiconductor substrate and the second semiconductor substrate are made of different materials.

2. The chip-stacked image sensor of claim 1, wherein the first semiconductor substrate is a Ge, SiGe, GaAs, GaN, InP, InGaAs or InGaZnO substrate.

3. The chip-stacked image sensor of claim 1, wherein the first semiconductor substrate is an epitaxial substrate obtained by allowing Ge, SiGe, GaAs, GaN, InP, InGaAs or InGaZnO to grow into a single crystal on a silicon (Si) substrate.

4. The chip-stacked image sensor of claim 1, wherein the first semiconductor substrate is a GeOI, SiGeOI, GaAsOI, GaNOI, InPOI, InGaAsOI or InGaZnOOI substrate having silicon-on-insulator (SOI) characteristics.

5. The chip-stacked image sensor of claim 2, wherein the second semiconductor substrate is a silicon (Si) substrate.

6. The chip-stacked image sensor of claim 5, wherein the circuit region has formed therein a transmission transistor, a reset transistor, a source follower transistor, a blocking switch transistor, a read-out circuit, a vertical/horizontal decoder, a correlated double sampling (CDS) circuit which is involved in a sensor operation and image quality, an analog circuit, an analog-digital converter (ADC) and a digital circuit.

7. A chip-stacked image sensor having a heterojunction structure, the chip-stacked image sensor comprising:
a first semiconductor chip having, formed on a first semiconductor substrate, a photodiode, a transmission transistor configured to transmit an image charge, which corresponds to an image signal sensed by the photodiode, to a floating diffusion region, and a first pad configured to transfer the image charge, which corresponds to the image signal sensed by the photodiode, to an outside of the first semiconductor substrate; and
a second semiconductor chip having, formed on a second semiconductor substrate, a second pad that is bonded to the first pad, and a circuit region configured to output the image signal, transferred from the first semiconductor chip, to the outside of the second semiconductor chip,
wherein the first semiconductor substrate and the second semiconductor substrate are made of different materials.

8. The chip-stacked image sensor of claim 7, wherein the first semiconductor substrate is a Ge, SiGe, GaAs, GaN, InP, InGaAs or InGaZnO substrate.

9. The chip-stacked image sensor of claim 7, wherein the first semiconductor substrate is an epitaxial substrate obtained by allowing Ge, SiGe, GaAs, GaN, InP, InGaAs or InGaZnO to grow into a single crystal on a silicon (Si) substrate.

10. The chip-stacked image sensor of claim 7, wherein the first semiconductor substrate is a GeOI, SiGeOI, GaAsOI, GaNOI, InPOI, InGaAsOI or InGaZnOOI substrate having silicon-on-insulator (SOI) characteristics.

11. The chip-stacked image sensor of claim 8, wherein the second semiconductor substrate is a silicon (Si) substrate.

12. The chip-stacked image sensor of claim 11, wherein the circuit region has formed therein a reset transistor, a source follower transistor, a blocking switch transistor, a read-out circuit, a vertical/horizontal decoder, a correlated double sampling (CDS) circuit which is involved in a sensor operation and image quality, an analog circuit, an analog-digital converter (ADC) and a digital circuit.

13. A method for manufacturing a chip-stacked image sensor having a heterojunction structure, the method comprising the steps of:
forming a first semiconductor chip having, formed on a first semiconductor substrate, a photodiode and a first pad configured to transfer an image charge, which corresponds to an image signal sensed by the photodiode, to an outside of the first semiconductor substrate;
forming a second semiconductor chip having, formed on a second semiconductor substrate, a second pad that is bonded to the first pad, and a circuit region configured to output the image charge, transferred from the first semiconductor chip, to the outside of the second semiconductor chip;
etching the first semiconductor chip and the second semiconductor chip so as to project the first pad and the second pad; and
bonding the first semiconductor chip and the second semiconductor chip to each other by brining the projected first pad and second pad into contact with each other so as to face each other,
wherein the first semiconductor substrate and the second semiconductor substrate are made of different materials.

14. The method of claim 13, wherein the step of forming the first semiconductor chip is a step of forming the first semiconductor chip using the first semiconductor substrate made of Ge, SiGe, GaAs, GaN, InP, InGaAs or InGaZnO.

15. The method of claim 13, wherein the step of forming the first semiconductor chip is a step of forming the first semiconductor chip using the first semiconductor substrate obtained by allowing Ge, SiGe, GaAs, GaN, InP, InGaAs or InGaZnO to epitaxially grow into a single crystal on a silicon (Si) substrate.

16. The method of claim 13, wherein the step of forming the first semiconductor chip is a step of forming the first semiconductor chip using the first semiconductor substrate made of GeOI, SiGeOI, GaAsOI, GaNOI, InPOI, InGaAsOI or InGaZnOOI having silicon-on-insulator (SOI) characteristics.

17. The method of claim 14, wherein the step of forming the second semiconductor chip is a step of forming the second semiconductor chip using the second semiconductor substrate made of silicon (Si).

18. The method of claim 17, wherein the step of forming the second semiconductor chip is a step of forming the circuit region having formed therein a transmission transistor, a reset transistor, a source follower transistor, a blocking switch transistor, a read-out circuit, a vertical/horizontal decoder, a correlated double sampling (CDS) circuit which is involved in a sensor operation and image quality, an analog circuit, an analog-digital converter (ADC) and a digital circuit.

19. The method of claim 13, wherein the step of bonding the semiconductor chips is a step of bonding the first semiconductor chip and the second semiconductor chip to each other using a Cu oxide fusion bonding, metal thermo-compression bonding, eutectic bonding method or direct bonding method.

20. A method for manufacturing a chip-stacked image sensor having a heterojunction structure, the method comprising the steps of:
forming a first semiconductor chip having, formed on a first semiconductor substrate, a photodiode, a transmission transistor configured to transmit an image charge, which corresponds to an image signal sensed by the photodiode, to a floating diffusion region, and a first pad configured to transfer the image charge, which corresponds to the image signal sensed by the photodiode, to an outside of the first semiconductor substrate;
forming a second semiconductor chip having, formed on a second semiconductor substrate, a second pad that is bonded to the first pad, and a circuit region configured to output the image signal, transferred from the first semiconductor chip, to the outside of the second semiconductor chip;
etching the first semiconductor chip and the second semiconductor chip so as to project the first pad and the second pad; and
bonding the first semiconductor chip and the second semiconductor chip to each other by brining the projected first pad and second pad into contact with each other so as to face each other,
wherein the first semiconductor substrate and the second semiconductor substrate are made of different materials.

21. The method of claim 20, wherein the step of forming the first semiconductor chip is a step of forming the first semiconductor chip using the first semiconductor substrate made of Ge, SiGe, GaAs, GaN, InP, InGaAs or InGaZnO.

22. The method of claim 20, wherein the step of forming the first semiconductor chip is a step of forming the first semiconductor chip using the first semiconductor substrate obtained by allowing Ge, SiGe, GaAs, GaN, InP, InGaAs or InGaZnO to epitaxially grow into a single crystal on a silicon (Si) substrate.

23. The method of claim 20, wherein the step of forming the first semiconductor chip is a step of forming the first semiconductor chip using the first semiconductor substrate made of GeOI, SiGeOI, GaAsOI, GaNOI, InPOI, InGaAsOI or InGaZnOOI having silicon-on-insulator (SOI) characteristics.

24. The method of claim 21, wherein the step of forming the second semiconductor chip is a step of forming the second semiconductor chip using the second semiconductor substrate made of silicon (Si).

25. The method of claim 24, wherein the step of forming the second semiconductor chip is a step of forming the circuit region having formed therein a reset transistor, a source follower transistor, a blocking switch transistor, a read-out circuit, a vertical/horizontal decoder, a correlated double sampling (CDS) circuit which is involved in a sensor operation and image quality, an analog circuit, an analog-digital converter (ADC) and a digital circuit.

26. The method of claim 20, wherein the step of bonding the semiconductor chips is a step of bonding the first semiconductor chip and the second semiconductor chip to each other using a Cu oxide fusion bonding, metal thermo-compression bonding, eutectic bonding method or direct bonding method.
